(19) United States
(12) Patent Application Publication
(10) Pub. No.: US 2019/0057935 A1
(43) Pub. Date: Feb. 21, 2019

(54) SEMICONDUCTOR STRUCTURE AND FABRICATION METHOD THEREOF

(71) Applicants: UNITED MICROELECTRONICS CORP., Hsin-Chu City (TW); Fujian Jinhua Integrated Circuit Co., Ltd., Quanzhou City (CN)

(72) Inventor: Yukihiro Nagai, Saijo City (JP)

(21) Appl. No.: 15/705,267

(22) Filed: Sep. 15, 2017

(30) Foreign Application Priority Data
Aug. 17, 2017 (CN) 201710704697.4

(51) Int. Cl. H01L 23/528; H01L 23/535; H01L 23/522; H01L 23/532; H01L 21/768

(52) U.S. Cl. CPC H01L 23/5283; H01L 23/535; H01L 23/5226; H01L 21/02178; H01L 23/53271; H01L 21/76895; H01L 21/76897; H01L 23/53266

(57) ABSTRACT

A semiconductor structure is disclosed. The semiconductor structure includes a first interlayer dielectric (ILD) layer disposed on a semiconductor substrate. A metal pad is disposed in the first ILD layer. A contact self-alignment structure is disposed on the first ILD layer. The contact self-alignment structure has an opening that is disposed directly above the metal pad. A second interlayer dielectric (ILD) layer is disposed on the first ILD layer. A contact plug penetrates through the second ILD layer and is electrically connected to the metal pad via the opening of the contact self-alignment structure.

### CROSS REFERENCE TO RELATED APPLICATION

This application claims the priority from CN application No. 201710704697.4, filed Aug. 17, 2017, which is included in its entirety herein by reference.

### BACKGROUND OF THE INVENTION

### 1. Field of the Invention

The present invention relates to the field of semiconductor technology, and in particular to a semiconductor structure and a method of making the same.

### 2. Description of the Prior Art

Typically, a DRAM semiconductor device includes a memory cell region, a peripheral circuit region, and a core circuit region. The memory cell area is used to store data. The peripheral circuit region can be used to convert an external voltage signal to an internal voltage signal or for signal transmission within a semiconductor chip. When the data is to be written to the memory unit or to read the data stored in the memory unit, the core circuit region is used to selectively control the word lines and the bit lines connected to the corresponding memory cells.

In general, a pattern having a minimum width is formed in the memory cell region of the DRAM, and the peripheral circuit region is provided with a pattern having a width wider than that of the memory cell region and a larger vacant area. The core circuit region is provided with a signal amplifying means called a sense amplifier which comprises a very fine and complicated circuit. That is, the core circuit region requires fine line design rules that correspond to the memory cell area.

The drawback of the prior art is that the contact plug in the core circuit region is made only after the capacitor structure of the memory cell region is completed, so that the contact hole must be formed by dry etching through a thicker dielectric layer (a thickness greater than the height of the capacitor), and the width of the contact pad area of the core circuit region is limited by the above-mentioned fine line design rule, so the line width is very small and difficult to align, and it is not easy to determine the etch end point when etching the etched hole, which leads to yield loss when etching the contact holes in the core circuit region.

### SUMMARY OF THE INVENTION

It is one object of the present invention to provide a semiconductor device and a method of making the same, which can improve the deficiencies and disadvantages of the prior art.

According to one embodiment of the present invention, a semiconductor structure is disclosed. The semiconductor structure includes a first interlayer dielectric (ILD) layer disposed on a semiconductor substrate. A metal pad is disposed in the first ILD layer. A contact self-alignment structure is disposed on the first ILD layer. The contact self-alignment structure has an opening that is disposed directly above the metal pad. A second interlayer dielectric (ILD) layer is disposed on the first ILD layer. A contact plug penetrates through the second ILD layer and is electrically connected to the metal pad via the opening of the contact self-alignment structure.

According to another embodiment of the present invention, a method for fabricating a semiconductor structure is disclosed. A semiconductor substrate is provided. A first interlayer dielectric (ILD) layer is formed on the semiconductor substrate. A metal pad is formed in the first ILD layer. A contact self-alignment structure is formed on the first ILD layer. The contact self-alignment structure comprises an opening that is disposed directly above the metal pad. A second interlayer dielectric (ILD) layer is formed on the first ILD layer. A contact plug penetrating through the second ILD layer and the first ILD layer is formed

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 5 are schematic cross-sectional views showing a method of fabricating a semiconductor structure according to one embodiment of the present invention.

FIG. 6 is a schematic top view showing a contact self-alignment structure according to one embodiment of the present invention.

FIG. 7 is a schematic top view showing a contact self-alignment structure according to another embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments maybe utilized and structural changes may be made without departing from the scope of the present disclosure.

The following detailed description is, therefore, not to be taken in a limiting sense, and the scope of the present invention is defined only by the appended claims, along with the full scope of equivalents to which such claims are entitled. One or more implementations of the present invention will now be described with reference to the attached drawings, wherein like reference numerals are used to refer to like elements throughout, and wherein the illustrated structures are not necessarily drawn to scale.

As described in the embodiments herein, steps such as deposition, patterning or etching of various films (including conductive films, metals, dielectric layers, etc.) can be accomplished using known processes such as chemical vapor deposition, physical vapor deposition, sputtering, atomic layer deposition, optical lithography processes, plasma dry etching, wet etching, reactive ion etching, and the like, the details of which will not be repeated.

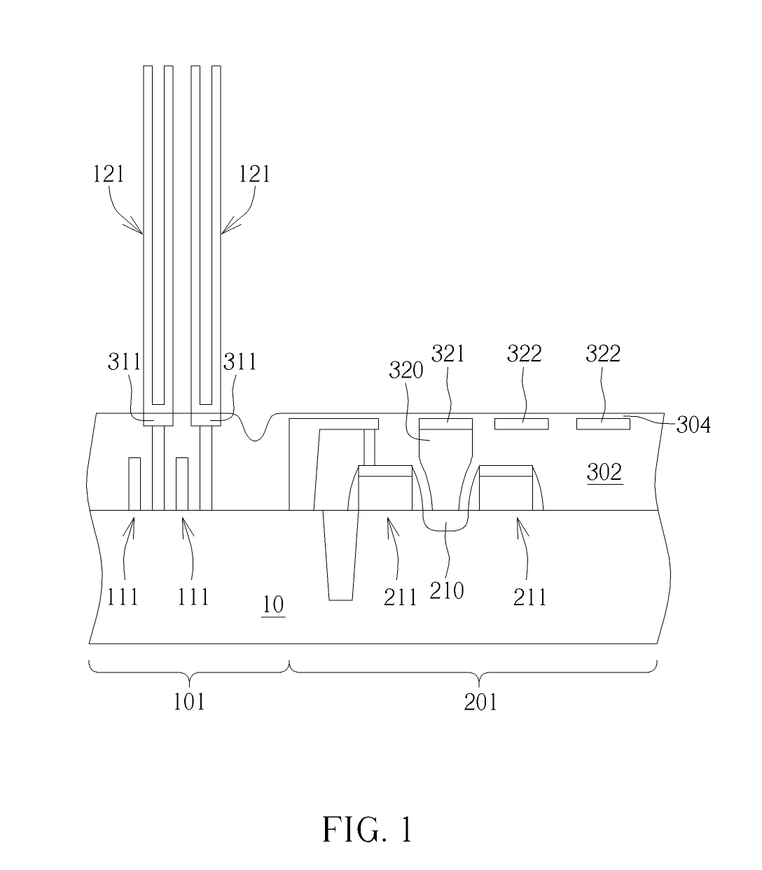

FIGS. 1 to 5 are schematic cross-sectional views showing a method of fabricating a semiconductor structure according to one embodiment of the present invention. As shown in FIG. 1, a semiconductor substrate 10 is first provided. The semiconductor substrate 10 comprises a memory array region 101 and a core circuit region 201. A plurality of memory cells 111 are formed in the memory array region 101, and a plurality of circuit elements 211, for example, MOS transistors and the like are formed in the core circuit region 201.

It is to be noted that the memory cells and circuit elements in the figures are illustrative only and their proportions are not shown in terms of the original size. A dopant region or an ion well may be additionally formed in the semiconductor substrate 10. In addition, structures such as a buried word lines may be formed in the memory array region 101. Since these structural features are well-known techniques, its details in the figure are also be omitted, for the sake of simplicity.

According to one embodiment of the present invention, the core circuit region 201 may comprise a Sense Amplifier (SA) and/or a Sub-Word Driver (SWD) circuit, etc., which includes very fine and complicated circuits. In general, the core circuit region 201 requires fine line design rules that correspond to the memory cell region.

According to one embodiment of the present invention, a first interlayer dielectric (ILD) layer 302 is formed on the semiconductor substrate 10, covering the memory array region 101 and the core circuit region 201. As shown in FIG. According to one embodiment of the present invention, the first ILD layer 302 includes, but is not limited to, silicon dioxide. According to one embodiment of the present invention, a metal pad 311 and a metal pad 321 are formed in the first ILD layer 302. According to one embodiment of the present invention, the metal pads 311 and 321 are formed in the M₀ metal layer.

According to one embodiment of the present invention, the metal pad 311 is formed in the memory array region 101 as a storage node contact pad, and the metal pad 321 is formed in the core circuit region 201 as a contact pad, which is electrically connected to the underlying conductive region 210 via a contact element 320. A fine line 322 may be formed around the metal pad 321. The line pitch of the metal pad 321 and the fine line 322 is equivalent to the line pitch in the memory array region 101 (for example, the line pitch of the word lines and the bit lines).

According to one embodiment of the present invention, an etch stop layer 304 may be additionally formed on the metal pad 321 and the first ILD layer 302. For example, the etch stop layer 304 may include silicon nitride, but is not limited thereto.

According to one embodiment of the present invention, at this point, a plurality of lower electrode structures 121 are formed on the metal pads 311 in the memory array region 101, respectively. The lower electrode structure 121 is composed of a conductive material such as titanium nitride or the like, and the lower electrode structure is connected to the metal pad 311. The method of manufacturing the lower electrode structure 121 is a well-known technique, and the details thereof are therefore omitted.

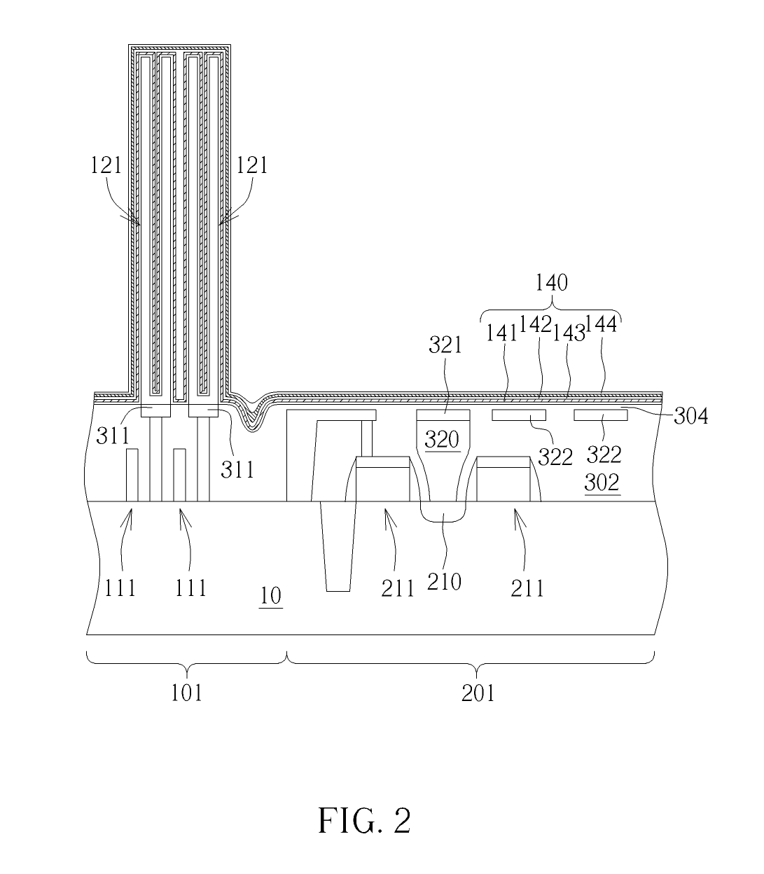

As shown in FIG. 2, after forming the lower electrode structure 121 in the memory array region 101, a high dielectric constant (high-k) layer 131 is formed on the semiconductor substrate 10 and covers the lower electrode structure 121. As shown in FIG. According to one embodiment of the present invention, in the memory array region 101, the high dielectric constant layer 131 conformally covers the surface of the lower electrode structure 121 as a capacitive dielectric layer, and in the core circuit region 201, the high dielectric constant layer 131 covers the etch stop layer 304 and is in direct contact with the etch stop layer 304.

According to one embodiment of the present invention, the dielectric constant of the high dielectric constant layer 131 is greater than or equal to 8. For example, the high dielectric constant layer 131 may comprise, but is not limited to, Al₂O₃, HfO₂, ZrO₂, or La₂O₃ .

Next, a capacitor upper electrode layer 140 is formed on the high dielectric constant layer 131. Next, According to one embodiment of the present invention, for example, the capacitor upper electrode layer 140 may comprise a titanium nitride layer 141, a polysilicon layer 142, a tungsten layer 143, and a hard mask layer 144. The hard mask layer 144 may comprise silicon nitride, but is not limited thereto. According to one embodiment of the present invention, the capacitor upper electrode layer 140 covers the memory array region 101 and the core circuit region 201.

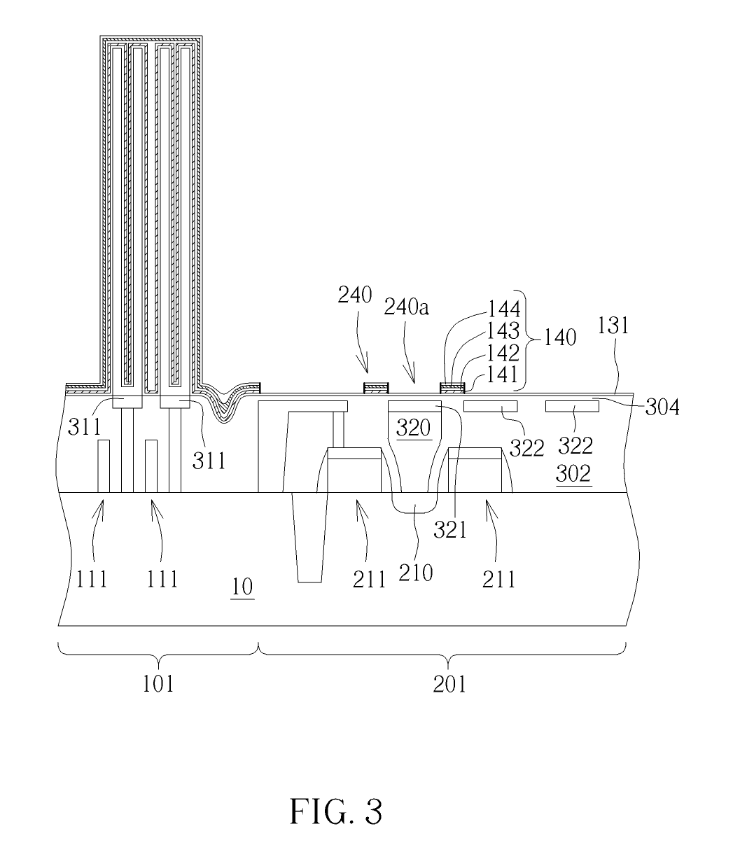

As shown in FIG. 3, a photolithography and etch process is then performed to pattern the capacitive upper electrode layer 140 into a contact self-alignment structure 240 in the core circuit region 201. The contact self-alignment structure 240 includes an opening 240 positioned directly above the metal pad 321, and is substantially aligned with the metal pad 321. The contact self-alignment structure 240 contacts the high dielectric constant layer 131 directly.

Since the contact self-alignment structure 240 is patterned from the capacitor upper electrode layer 140, the layer structure of the contact self-alignment structure 240 is identical to that of the capacitor upper electrode layer 140. In other words, the contact self-alignment structure 240 also includes titanium nitride layer 141, a polysilicon layer 142, a tungsten metal layer 143, and a hard mask layer 144 from top to bottom.

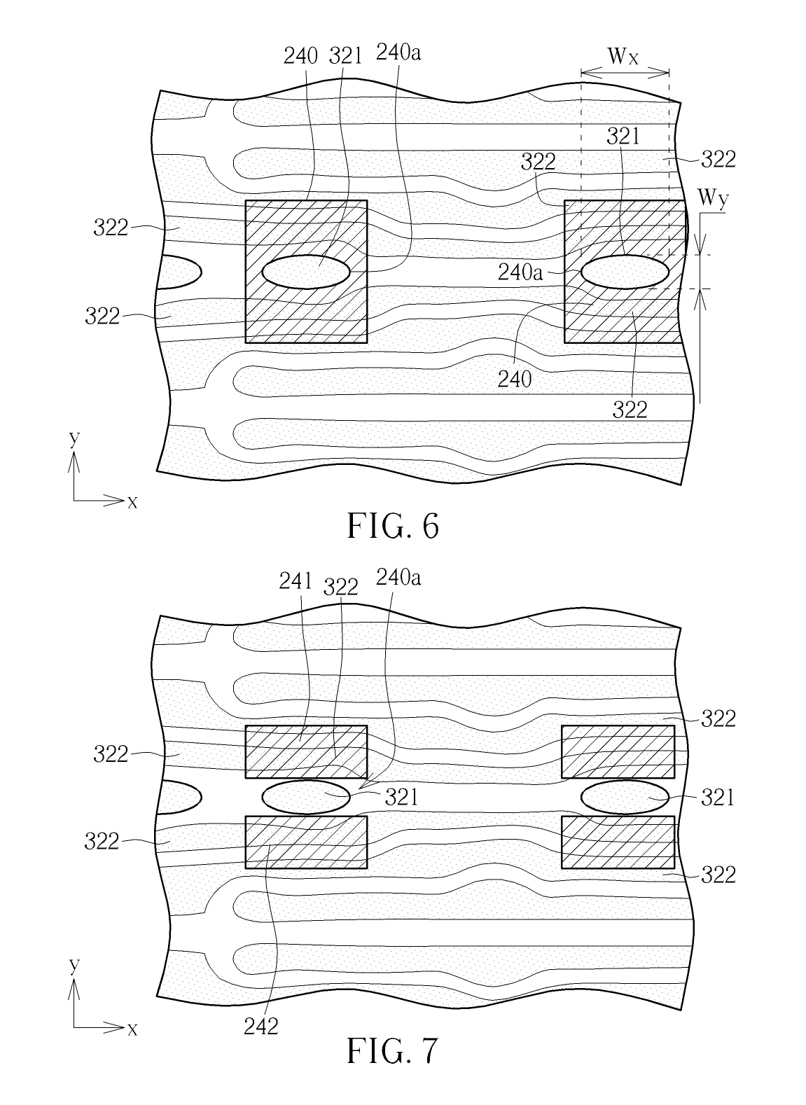

Please also refer to FIG. 6, which is a schematic top view of the contact self-alignment structure 240. In FIG. 6, the metal pad 321 and the fine line 322 under the self-alignment structure 240 are shown. According to one embodiment of the present invention, the contact self-alignment structure 240 may be a continuous, closed annular pattern surrounding the opening 240a.

According to one embodiment of the present invention, the contact self-alignment structure 240 may have a rectangular profile and an elliptical opening having a longer axis width wₓ and a shorter axis width w_{y}, wherein the shorter axis width w_{y} is less than or equal to a width w of the metal pad 321, for example, the width w may be less than or equal to 70 nm, but is not limited thereto.

According to one embodiment of the present invention, the contact self-alignment structure 240 is not necessarily a continuous, closed annular pattern. For example, the contact self-alignment structure 240 in FIG. 7 has a first portion 241 and a second portion 242 in which the first portion 241 and the second portion 242 are separated from each other and the opening 240a is disposed between the first portion 241 and the second portion 242.

According to one embodiment of the present invention, the first portion 241 and the second portion 242 may be long stripes or rectangular patterns arranged parallel to each other with a longer axis parallel to the reference x-axis in the figure. According to one embodiment of the present invention, the space between the first portion 241 and the second portion 242 (along the reference y-axis direction) is less than or equal to the width w of the metal pad 321.

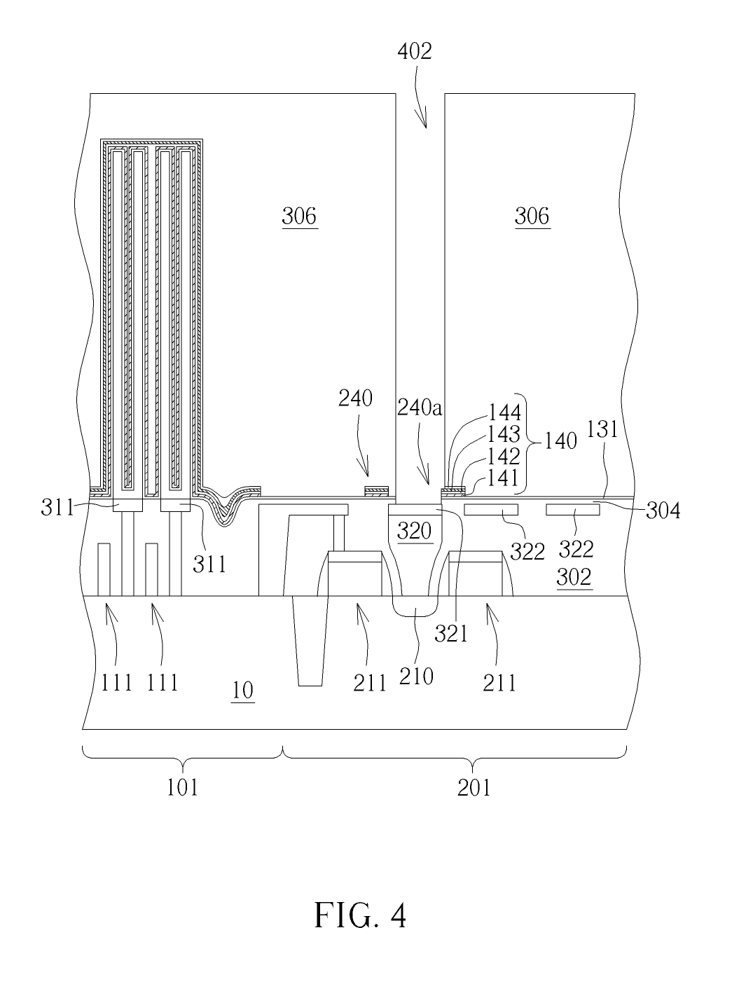

As shown in FIG. 4, a second interlayer dielectric layer 306 is formed on the memory array region 101 and the core circuit region 201. For example, the second interlayer dielectric layer 306 includes silicon oxide, silicon dioxide, BSG, BPSG, or the like.

The second interlayer dielectric layer 306 is deposited after the completion of the capacitor structure within the memory array region 101, and may be referred to as a post-memory dielectric (PMD) layer. According to one embodiment of the present invention, the thickness of the second interlayer dielectric layer 306 is greater than the height of the capacitor structure in the memory array region 101. According to one embodiment of the present invention, for example, the second interlayer dielectric layer 306 has a thickness of about 2 to 3 micrometers.

Subsequently, a lithography process and an etching process are performed to etch a contact hole 402 in the second interlayer dielectric layer 306. According to one embodiment of the present invention, the contact hole 402 extends through the second interlayer dielectric layer 306, the high dielectric constant layer 131, and the etch stop layer 304, partially exposing the top surface of the metal pad 321.

According to one embodiment of the present invention, during the etching of the contact hole 402 in the second interlayer dielectric layer 306, the bottom of the final contact hole 402 may be offset from the position of the metal pad 321 due to misalignment or the inclination of the etch angle. The contact self-alignment structure 240 provided on the first interlayer dielectric layer 302 enables the bottom of the contact hole 402 to be self-aligned with the opening 240a of the contact self-alignment structure 240. The tungsten layer 143 of the contact self-alignment structure 240 can resist etching, thereby improving the yield of contact hole etching.

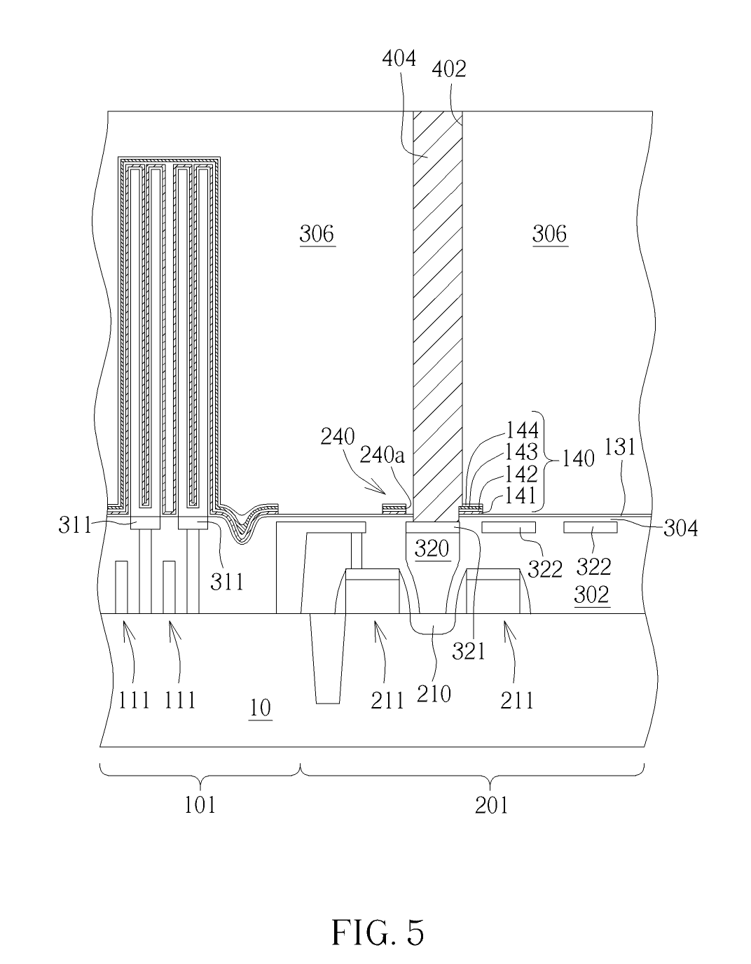

As shown in FIG. 5, after completion of the contact hole 402, a contact plug 404 is formed in the contact hole 402. The contact plug 404 extends through the second interlayer dielectric layer 306, the high dielectric constant layer 131, and the etch stop layer 304, electrically connected to the metal pad 321. According to one embodiment of the present invention, the contact plug 404 may comprise titanium nitride and/or tungsten, but is not limited thereto. Subsequently, the back end of line (BEOL) metallization process may be performed to form metal interconnect structure (not shown).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a semiconductor substrate;
a first interlayer dielectric (ILD) layer on the semiconductor substrate;
a metal pad disposed in the first ILD layer;
a contact self-alignment structure disposed on the first ILD layer, wherein the contact self-alignment structure comprises an opening that is disposed directly above the metal pad;
a second interlayer dielectric (ILD) layer on the first ILD layer; and
a contact plug penetrating through the second ILD layer and the first ILD layer.

2. The semiconductor structure according to claim 1, wherein the contact self-alignment structure has an annular pattern encircling the opening.

3. The semiconductor structure according to claim 2, wherein the contact self-alignment structure has a rectangular outline.

4. The semiconductor structure according to claim 1, wherein the opening has an oval shape having a longer axis width and a shorter axis width.

5. The semiconductor structure according to claim 4, wherein the shorter axis width is equal to or smaller than a width of the metal pad.

6. The semiconductor structure according to claim 1, wherein the contact self-alignment structure has a first portion and a second portion that are separated from each other, with the opening disposed therebetween.

7. The semiconductor structure according to claim 6, wherein a space between the first portion and the second portion is equal to or smaller than a width of the metal pad.

8. The semiconductor structure according to claim 1, wherein the contact self-alignment structure comprises a tungsten layer.

9. The semiconductor structure according to claim 8, wherein the contact self-alignment structure further comprises a polysilicon layer under the tungsten layer.

10. The semiconductor structure according to claim 9, wherein the contact self-alignment structure further comprises a titanium nitride layer under the polysilicon layer.

11. The semiconductor structure according to claim 1, wherein the contact plug is electrically connected to the metal pad via the opening of the contact self-alignment structure.

12. A method for fabricating a semiconductor structure, comprising:
providing a semiconductor substrate;
forming a first interlayer dielectric (ILD) layer on the semiconductor substrate;
forming a metal pad in the first ILD layer;
forming a contact self-alignment structure on the first ILD layer, wherein the contact self-alignment structure comprises an opening that is disposed directly above the metal pad;
forming a second interlayer dielectric (ILD) layer on the first ILD layer; and
forming a contact plug penetrating through the second ILD layer and the first ILD layer.

13. The method for fabricating a semiconductor structure according to claim 12 further comprising:
before forming the contact self-alignment structure on the first ILD layer, forming an etch stop layer on the metal pad and the first ILD layer; and
forming a high dielectric constant (high-k) dielectric layer on the etch stop layer, wherein the contact plug penetrates through the second ILD layer, the high-k dielectric layer and the etch stop layer.

14. The method for fabricating a semiconductor structure according to claim 13, wherein the high-k dielectric layer comprises Al₂O₃, HfO₂, ZrO₂ or La₂O₃.

15. The method for fabricating a semiconductor structure according to claim 13, wherein the contact self-alignment structure is indirect contact with the high-k dielectric layer.

16. The method for fabricating a semiconductor structure according to claim 15, wherein the contact self-alignment structure comprises a tungsten layer.

17. The method for fabricating a semiconductor structure according to claim 16, wherein the contact self-alignment structure further comprises a polysilicon layer under the tungsten layer.

18. The method for fabricating a semiconductor structure according to claim 17, wherein the contact self-alignment structure further comprises a titanium nitride layer under the polysilicon layer.

19. The method for fabricating a semiconductor structure according to claim 18, wherein the contact self-alignment structure further comprises a hard mask layer on the tungsten layer.

20. The method for fabricating a semiconductor structure according to claim 12, wherein the contact plug is electrically connected to the metal pad via the opening of the contact self-alignment structure.
